(19) United States
(12) Patent Application Publication
(10) Pub. No.: US 2011/0142090 A1
(43) Pub. Date: Jun. 16, 2011

(54) LASER DIODE AND METHOD OF MANUFACTURING LASER DIODE

(75) Inventors: Mikihiro Yokozeki, Kanagawa (JP); Junji Sawahata, Miyagi (JP); Katsunori Yanashima, Kanagawa (JP); Miwa Okubo, Kanagawa (JP)

(73) Assignee: Sony Corporation, Tokyo (JP)

(21) Appl. No.: 12/962,252

(22) Filed: Dec. 7, 2010

(30) Foreign Application Priority Data
Dec. 14, 2009 (JP) 2009-283447

(51) Int. Cl. H01S 5/22; H01L 21/78

(52) U.S. Cl. 372/46.012; 438/33; 257/E21.599

(57) ABSTRACT

A laser diode includes: a substrate; a semiconductor layer including a lower cladding layer, an active layer, and an upper cladding layer; a strip-shaped ridge provided on an upper cladding layer side in the semiconductor layer; and a pair of resonator end faces sandwiching the semiconductor layer and the ridge. The substrate includes strip-shaped grooves provided on both sides of a portion facing the ridge along the portion facing the ridge, and extending in a direction different from a direction orthogonal to the extending direction of the ridge, and L₁, L₂, and L₃ satisfy the following relationship,

L₁<L₃/2

L₂≦L₃/3

where L₁ is a length of each groove, L₂ is a length of a groove non-form rectangular region in the extending direction of the ridge, the groove non-form rectangular region being sandwiched by the grooves from the extending direction of the ridge, and L₃ is a resonator length.

### BACKGROUND OF THE INVENTION

1. Field of the Invention

The present invention relates to a laser diode using a substrate in which a groove is formed, and a method of manufacturing the same.

2. Description of the Related Art

Recently, a method of manufacturing a GaN substrate which has been difficult so far is developed, and a nitride laser diode is put into practical use correspondingly. However, it is difficult to manufacture a high-quality GaN substrate, and, for example, a fluctuation of a plane direction, and a variation of an off angle are likely to be generated in the substrate. These deteriorate flatness of an epitaxial crystal growth plane, and cause deterioration of device characteristics and reliability.

In the case of a GaN material, unlike a GaAs material, the lattice constant is highly different in GaN, and materials such as AlGaN, and freedom in design of an Al composition ratio is low. Thus, according to circumstances, cracks are generated when forming a device, and unevenness of the epitaxial crystal growth plane is increased due to a strain in an epitaxial layer.

For example, in Japanese Unexamined Patent Publication No. 2005-236109, for suppressing generation of the cracks, and forming a nitride semiconductor layer having favorable surface flatness, it is disclosed to form stripe grooves and stripe hills on a top face of a nitride semiconductor substrate (wafer), and form the nitride semiconductor layer on bottom faces of the grooves and top faces of the hills.

### SUMMARY OF THE INVENTION

However, even when the nitride semiconductor layer is formed on the surface of the wafer described in Japanese Unexamined Patent Publication No. 2005-236109, relaxation of the strain is considered insufficient. Actually, for example, as illustrated in FIG. 10, when a plurality of ridge stripes 410 extending from end to end of a wafer 400, and a plurality of grooves 420 extending from end to end of the wafer 400 are formed and alternately aligned on the surface of the wafer 400, unevenness is generated in a portion of the ridge stripes 410. This indicates that the strain is not sufficiently relaxed even when the grooves 420 are formed.

In this manner, in the technique of the past, there is an issue that it is difficult to sufficiently relax the strain.

In view of the foregoing, it is desirable to provide a laser diode in which a strain is sufficiently relaxed, and a method of manufacturing the same.

According to an embodiment of the present invention, there is provided a first laser diode including: a semiconductor layer on a substrate. The semiconductor layer includes a lower cladding layer, an active layer, and an upper cladding layer in this order from a substrate side. A strip-shaped ridge is provided on an upper cladding layer side in the semiconductor layer. The laser diode further includes a pair of resonator end faces sandwiching the semiconductor layer and the ridge from an extending direction of the ridge. The substrate includes a plurality of strip-shaped grooves. Each groove is arranged on both sides of a portion facing the ridge along the portion facing the ridge, and extends in a direction different from a direction orthogonal to the extending direction of the ridge. L₁, L₂, and L₃ satisfy the following relationship,

L₁<L₃/2

L₂≦L₃/3

where L₁ is a length of each groove, L₂ is a length of a groove non-form rectangular region in the extending direction of the ridge, the groove non-form rectangular region being sandwiched by the grooves from the extending direction of the ridge, and L₃ is a resonator length.

In the first laser diode according to the embodiment of the present invention, the plurality of strip-shaped grooves satisfying the relationship are formed on the both sides of the portion facing the ridge in the substrate, along the portion facing the ridge. Therefore, when the ridge is formed on the substrate in a manufacturing process, unevenness in the ridge is reduced.

According to another embodiment of the present invention, there is provided a second laser diode including: a semiconductor layer on a substrate. The semiconductor layer includes a lower cladding layer, an active layer, and an upper cladding layer in this order from a substrate side. A strip-shaped ridge is provided on an upper cladding layer side in the semiconductor layer. The laser diode further includes a pair of resonator end faces sandwiching the semiconductor layer and the ridge from an extending direction of the ridge. The substrate includes a plurality of strip-shaped grooves. Each groove is arranged on both sides of a portion facing the ridge along the portion facing the ridge, and meanders.

In the second laser diode according to the embodiment of the present invention, the plurality of strip-shaped meandering grooves are formed on the both sides of the portion facing the ridge in the substrate, along the portion facing the ridge. Therefore, when the ridge is formed on the substrate in a manufacturing process, unevenness in the ridge is reduced.

According to another embodiment of the present invention, there is provided a third laser diode including: a semiconductor layer on a substrate. The semiconductor layer includes a lower cladding layer, an active layer, and an upper cladding layer in this order from a substrate side. A strip-shaped ridge is provided on an upper cladding layer side in the semiconductor layer. The laser diode further includes a pair of resonator end faces sandwiching the semiconductor layer and the ridge from an extending direction of the ridge. The substrate includes a pair of side faces facing in a direction orthogonal to the extending direction of the ridge, and includes a plurality of strip-shaped notches on both of the pair of side faces. L₁, L₂, and L₃ satisfy the following relationship,

L₁<L₃/2

L₂≦L₃/3

where L₁ is a length of each notch, L₂ is a length of a notch non-form region in the extending direction of the ridge, the notch non-form region being sandwiched by the notches from the extending direction of the ridge, and L₃ is a resonator length.

In the third laser diode according to the embodiment of the present invention, the plurality of strip-shaped notches satisfying the relationship are formed on both of the pair of side faces of the substrate. Here, for example, when cutting the substrate in a manufacturing process, each notch is formed by cutting grooves provided on the substrate. In this manner, in the case where the grooves corresponding to the relational formula are provided on the substrate, when the ridge is formed in the manufacturing process, unevenness in the ridge is reduced.

According to another embodiment of the present invention, there is provided a first method of manufacturing a laser diode including the following three steps of:

(A1) a first step of preparing a substrate including a plurality of strip-shaped grooves provided on both sides of each strip-shaped region where a plurality of strip-shaped ridges will be formed later, along the strip-shaped region, and satisfying the following relational formula,

L₁<L₃/2

L₂≦L₃/3

where L₁ is a length of each groove, L₂ is a length of a groove non-form rectangular region in the extending direction of the ridge, the groove non-form rectangular region being sandwiched by the grooves from the extending direction of the ridge, and L₃ is a resonator length;

(A2) a second step of forming a semiconductor layer including a lower cladding layer, an active layer, and an upper cladding layer in this order from a substrate side on a surface of the substrate, and forming the plurality of ridges on an upper cladding layer side in the semiconductor layer; and

(A3) a third step of cutting the substrate into chips.

In the first method of manufacturing the laser diode according to the embodiment of the present invention, the plurality of strip-shaped grooves which satisfy the relational formula are formed on the both sides of each strip-shaped region where the plurality of strip-shaped ridges will be formed later in the substrate. Therefore, when the ridge is formed on the substrate, unevenness in the ridge is reduced.

According to another embodiment of the present invention, there is provided a second method of manufacturing a laser diode including the following three steps of:

(B1) a first step of preparing a substrate including a plurality of strip-shaped meandering grooves provided on both sides of each strip-shaped region where a plurality of strip-shaped ridges will be formed later, along the strip-shaped region;

(B2) a second step of forming a semiconductor layer including a lower cladding layer, an active layer, and an upper cladding layer in this order from a substrate side on a surface of the substrate, and forming the plurality of ridges on an upper cladding layer side in the semiconductor layer; and

(B3) a third step of cutting the substrate into chips.

In the second method of manufacturing the laser diode according to the embodiment of the present invention, the plurality of strip-shaped meandering grooves are formed on the both sides of each strip-shaped region where the plurality of strip-shaped ridges will be formed later in the substrate. Therefore, when the ridge is formed on the substrate, unevenness in the ridge is reduced.

According to the first laser diode to the third laser diode, and the first method of manufacturing the laser diode and the second method of manufacturing the laser diode of the embodiments of the present invention, when the ridge is formed on the substrate, since the unevenness in the ridge is reduced, it may be possible to realize the laser diode in which a strain is sufficiently relaxed. As a result, it may be possible to suppress deterioration of device characteristics and reliability in the laser diode.

Other and further objects, features and advantages of the invention will appear more fully from the following description.

### BRIEF DESCRIPTION OF THE DRAWINGS

FIGS. 1A and 1B are a top face view and a cross-sectional view, respectively, of a laser diode according to a first embodiment of the present invention.

FIG. 2 is a top face view of a substrate of FIGS. 1A and 1B.

FIGS. 3A and 3B are top face views of a wafer in a manufacturing process of the laser diode of FIGS. 1A and 1B.

FIGS. 4A and 4B are a top face view and a cross-sectional view, respectively, of the laser diode according to a second embodiment of the present invention.

FIG. 5 is a top face view of the substrate of FIGS. 4A and 4B.

FIGS. 6A and 6B are top face views of the wafer in the manufacturing process of the laser diode of FIGS. 4A and 4B.

FIGS. 7A and 7B are a top face view and a cross-sectional view, respectively, of a laser diode according to a third embodiment of the present invention.

FIG. 8 is a top face view of the substrate of FIGS. 7A and 7B.

FIGS. 9A and 9B are top face views of the wafer in the manufacturing process of the laser diode of FIGS. 7A and 7B.

FIG. 10 is a top face view of a wafer in a manufacturing process of a laser diode of the related art.

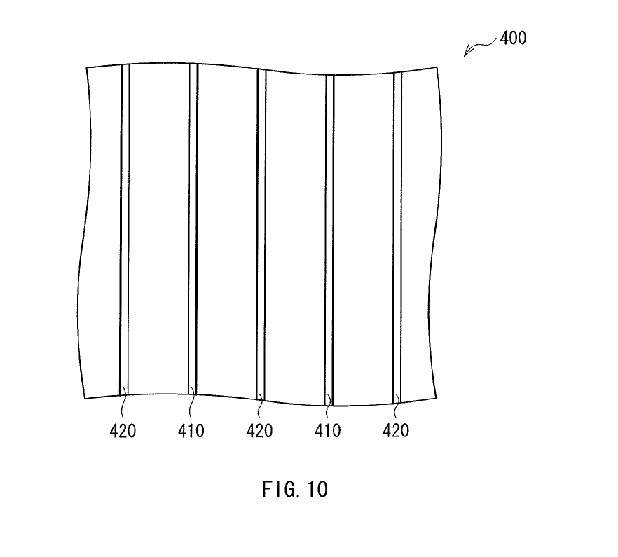

### DETAILED DESCRIPTION OF THE PREFERRED EMBODIMENTS

Hereinafter, a description will be made on embodiments of the present invention with reference to the drawings. In addition, the description will be made in the following order.

1. First embodiment (example where a straight groove is formed on a side of a ridge)

2. Second embodiment (example where a meandering groove is formed on the side of the ridge)

3. Third embodiment (example where a notch is formed on an end face of a chip)

### 1. First Embodiment

(Structure of Laser Diode 1)

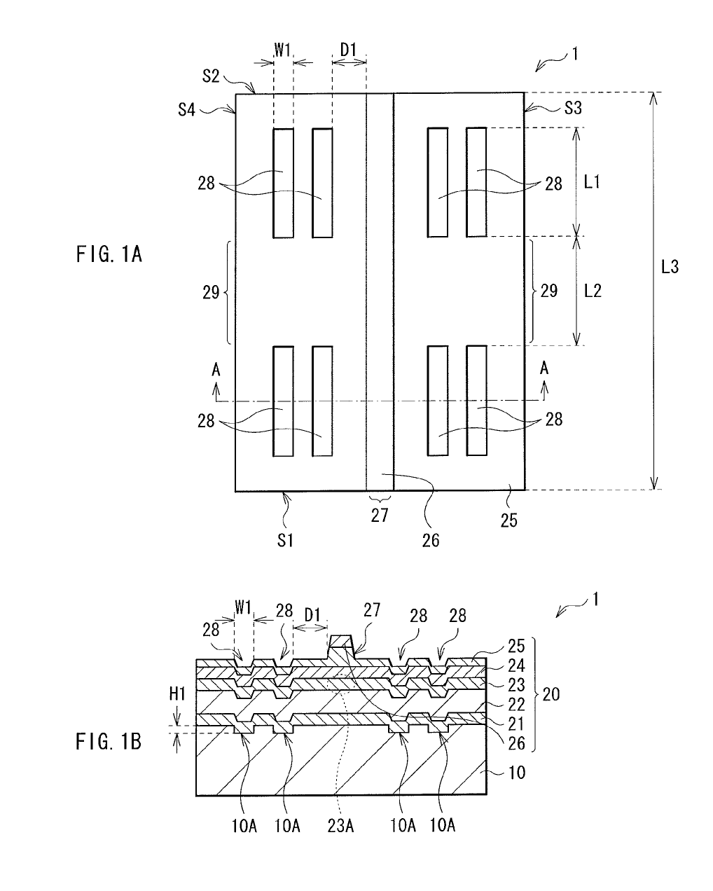

FIG. 1A illustrates an example of a top face structure of a laser diode 1 according to a first embodiment of the present invention. FIG. 1B illustrates an example of a cross-sectional structure as viewed from the direction of arrow A-A of the laser diode 1 of FIG. 1A. In addition, FIGS. 1A and 1B are schematic illustrations, and are different from actual dimensions and actual shapes.

The laser diode 1 has a structure in which a semiconductor layer 20 which will be described later is sandwiched by a pair of resonator end faces (a front end face S₁ and a rear end face S₂) from a resonator direction (extending direction of a ridge 27). Therefore, the laser diode 1 is a kind of so-called edge emitting laser diode. This laser diode 1 includes, for example, the semiconductor layer 20 including a buffer layer 21, a lower cladding layer 22, an active layer 23, an electron blocking layer 24, an upper cladding layer 25, and a contact layer 26 in this order from a substrate 10 side on the substrate 10. In the semiconductor layer 20, layers (for example, a guide layer) other than the above-described layers may be additionally provided. Further, in the semiconductor layer 20, a part of the above-described layers (for example, the buffer layer 21, and the electron blocking layer 24) may be omitted.

The substrate 10 is made of, for example, a group III-V nitride semiconductor such as GaN. Here, the expression “group III-V nitride semiconductor” indicates a semiconductor containing at least one kind of group 3B elements in the short-period type periodic table, and at least N of group 5B elements in the short-period type periodic table. Examples of the group III-V nitride semiconductor include a nitride gallium compound containing Ga and N. Examples of the nitride gallium compound include GaN, AlGaN, and AlGaInN. The group III-V nitride semiconductor is doped with n-type impurities of group IV elements or group VI elements such as Si, Ge, O, and Se, or p-type impurities of group II elements or group IV elements such as Mg, Zn, and C, if necessary.

The semiconductor layer 20 mainly contains, for example, the group III-V nitride semiconductor. The buffer layer 21 is, for example, composed of GaN. The lower cladding layer 22 is, for example, composed of AlGaN. The active layer 23 has, for example, a multiquantum well structure in which a well layer and a barrier layer which are formed of GaInN having different composition ratios, respectively, are alternately stacked. The electron blocking layer 24 is, for example, composed of AlGaN. The upper cladding layer 25 is, for example, composed of AlGaN. The contact layer 26 is, for example, composed of GaN.

In the upper part of the semiconductor layer 20, specifically, in the upper part of the upper cladding layer 25 and the contact layer 26, the strip-shaped ridge 27 is formed. The ridge 27 is, for example, in a straight line shape as viewed from the stacking direction of the semiconductor layer 20. The ridge 27 constitutes an optical waveguide in cooperation with both sides of the ridge 27 in the semiconductor layer 20. The ridge 27 confines light in the lateral direction by utilizing a refractive index difference in the lateral direction (direction orthogonal to the resonator direction), and constricts a current injected into the semiconductor layer 20. A portion immediately below the above-described optical waveguide in the active layer 23 corresponds to a current injection region, and this current injection region becomes a light emitting region 23A.

On the semiconductor layer 20, the pair of the front end face S₁ and the rear end face S₂ sandwiching the ridge 27 from the extending direction of the ridge 27 are formed. The front end face S₁ and the rear end face S₂ are formed by cutting a wafer 100 (will be described later) in a manufacturing process, and are, for example, cleavage faces formed by cleavage. A resonator is composed of the front end face S₁ and the rear end face S₂ in the stacked plane direction. In addition, the pair of the front end face S₁ and the rear end face S₂ of this embodiment corresponds to a specific example of “a pair of resonator end faces” of the present invention.

The front end face S₁ is a face emitting laser light, and a multilayer reflecting film (not illustrated in the figure) is formed on the surface of the front end face S₁. Meanwhile, the rear end face S₂ is a face reflecting the laser light, and a multilayer reflecting film (not illustrated in the figure) is formed on the surface of the rear end face S₂. The multilayer reflecting film on the front end face S₁ side is a low-reflectance film in which the reflectance of an emission-side end face composed of the corresponding multilayer reflecting film and the front end face S₁ is adjusted to be, for example, approximately 10%. Meanwhile, the multilayer reflecting film on the rear end face S₂ side is a high-reflectance film in which the reflectance of a reflection-side end face composed of the corresponding multilayer reflecting film and the rear end face S₂ is adjusted to be, for example, approximately 95%.

Further, on the semiconductor layer 20, a pair of side faces S₃ and S₄ sandwiching the ridge 27 from the direction orthogonal to the extending direction of the ridge 27 are formed. These side faces S₃ and S₄ are formed by cutting the wafer 100 (which will be described later) in the manufacturing process.

On the top face (the surface of the contact layer 26) of the ridge 27, an upper electrode (not illustrated in the figure) is provided. This upper electrode is, for example, configured by stacking Ti, Pt, and Au in this order, and electrically connected to the contact layer 26. Meanwhile, on the rear face of the substrate 10, a lower electrode (not illustrated in the figure) is provided. This lower electrode is, for example, configured by stacking an alloy of Au and Ge, Ni, and Au in this order from the substrate 10 side, and electrically connected to the substrate 10.

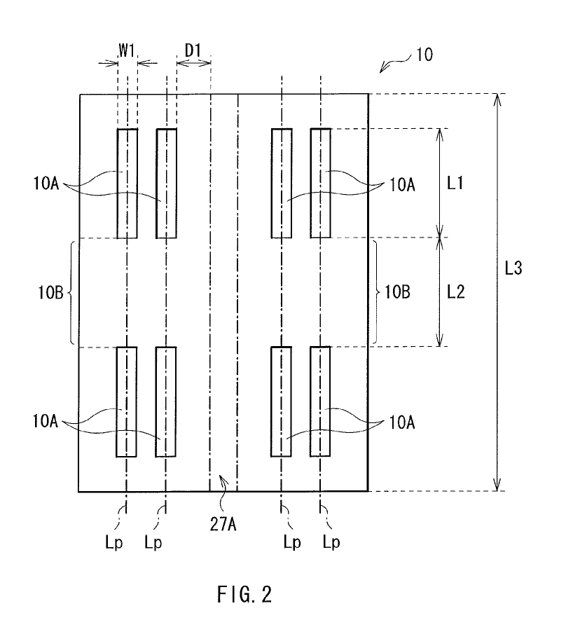

In this embodiment, for example, as illustrated in FIG. 2, a plurality of strip-shaped grooves 10A are provided on the top face (face in contact with the semiconductor layer 20) of the substrate 10. The plurality of grooves 10A are provided on both sides of a portion (strip-shaped region 27A) facing the ridge 27, along the strip-shaped region 27A. Each groove 10A extends in the direction different from the direction orthogonal to the extending direction of the ridge 27, and, for example, extends in the extending direction of the ridge 27.

Each groove 10A may, for example, extend in the direction intersecting the extending direction of the ridge 27 at an angle other than 90°. Further, although all the grooves 10A preferably extend in the same direction, a part of the grooves 10A may extend in the direction different from the direction of the other grooves 10A. Although each of the grooves 10A is preferably arranged to be bilaterally symmetric while the ridge 27 is positioned as a center line, each of the grooves 10A may be arranged to be bilaterally asymmetric.

Although a width W₁ of each groove 10A is not specifically limited, for example, the width W₁ is preferably set to be approximately 10 μm or less. Although a depth H₁ (FIG. 1B) of each groove 10A is not specifically limited, for example, the depth H₁ is preferably set to be approximately 10 μm or less. A distance D₁ between each groove 10A and the side face of the ridge 27 is preferably set to be 20 μm or more, and more preferably set to be 50 μm or more. This is because, in the case where the groove 10A is arranged too close to the ridge 27, when the ridge 27 is formed on the substrate 10 in the manufacturing process, there is a possibility that the composition of the ridge 27 is modulated. The distance D₁ is preferably set to be 100 μm or less. This is because, in the case where the groove 10A is arranged too far from the ridge 27, when the ridge 27 is formed on the substrate 10 in the manufacturing process, there is a possibility that large unevenness is generated in the ridge 27.

A length L₁ of each groove 10A in the resonator direction is, for example, preferably set to be shorter than L₃/2, where L₃ is a resonator length. This indicates that at least one groove non-form rectangular region 10B which will be described later exists on each of both sides of the strip-shaped region 27A in the top face of the substrate 10. The plurality of grooves 10A is arranged side by side in the extending direction of the ridge 27. For example, as illustrated in FIG. 2, although the plurality of grooves 10A are preferably arranged side by side on a line Lp which is parallel to the ridge 27, for example, though not illustrated in the figure, the plurality of grooves 10A may be arranged zigzag where the line Lp parallel to the ridge 27 is positioned as a center line.

For example, as illustrated in FIG. 2, on the top face of the substrate 10, a region (groove non-form rectangular region 10B) sandwiched by the grooves 10A from the extending direction of the ridge 27 exists. At least one groove non-form rectangular region 10B exists on each of the both sides of the ridge 27, and a length L₂ of each groove non-form rectangular region 10B in the resonator direction is, for example, preferably set to be L₃/3 or less.

In this embodiment, in each layer (the buffer layer 21, the lower cladding layer 22, the active layer 23, the electron blocking layer 24, and the upper cladding layer 25) in the semiconductor layer 20, strip-shaped recesses are formed immediately above each groove 10A formed on the substrate 10. In addition, in these recesses, the recess (recess of the upper cladding layer 25) exposed to the top face of the semiconductor layer 20 is described as a recess 28 in FIGS. 1A and 1B. The length of each recess in the semiconductor layer 20 in the resonator direction is set to be equal to the length L₁ of each groove 10A in the resonator direction (FIG. 1A). For example, as illustrated in FIG. 1A, on the top face of the semiconductor layer 20, a region (recess non-form rectangular region 29) sandwiched by the recesses 28 from the extending direction of the ridge 27 exists. The length of each recess non-form rectangular region 29 in the resonator direction is set to be equal to the length L₂ of each groove non-form rectangular region 10B in the resonator direction (FIG. 1A).

(Method of Manufacturing Laser Diode 1)

The laser diode 1 having such a structure may be manufactured, for example, as will be described next.

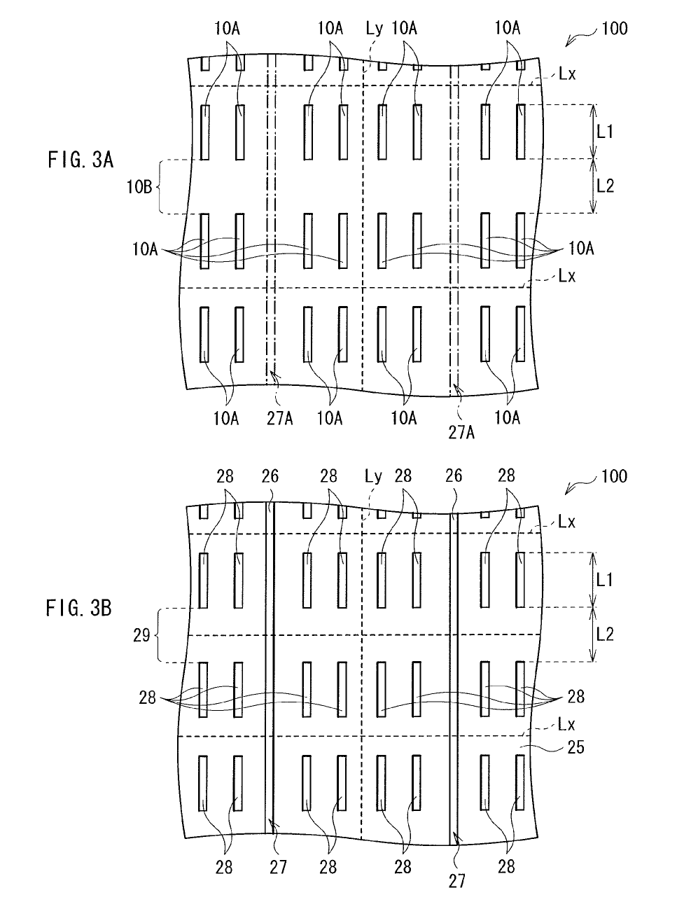

FIGS. 3A and 3B illustrate an example of the top face structure of the wafer 100 in the manufacturing process. In addition, broken lines Lx and Ly indicated in FIGS. 3A and 3B correspond to the positions where the wafer 100 will be cut later.

First, as a wafer to form the laser diode 1, the wafer 100 including the plurality of strip-shaped grooves 10A on the surface of the substrate 10 is prepared (FIG. 3A). The plurality of grooves 10A on the surface of the wafer 100 are formed on the both sides of each strip-shaped region 27A where the plurality of strip-shaped ridges 27 will be formed later, along the strip-shaped region 27A, and satisfy the following relational formula.

L₁<L₃/2

L₂≦L₃/3

Next, for example, the semiconductor layer 20 including the buffer layer 21, the lower cladding layer 22, the active layer 23, the electron blocking layer 24, the upper cladding layer 25, and the contact layer 26 in this order from the substrate 10 side is formed on the wafer 100, and the plurality of ridges 27 are formed in predetermined positions in the semiconductor layer 20 on the upper cladding layer 25 side (FIG. 3B). At this time, the recess 28 is formed immediately above each groove 10A on the surface of the semiconductor layer 20.

Next, although not illustrated in the figure, the upper electrode is formed on the top face of the ridge 27. Further, although not illustrated in the figure, the thickness of the substrate 10 is appropriately adjusted by lapping or the like, if necessary, and then the lower electrode is formed on the rear face of the substrate 10. Next, although not illustrated in the figure, the substrate 10 is cleaved on the broken line Lx, and the wafer 100 is in a bar shape. Therefore, one of the cleavage faces becomes the front end face S₁, and the other of the cleavage faces becomes the rear end face S₂. Thereafter, although not illustrated in the figure, the multilayer reflecting films are formed on the front end face S₁ and the rear end face S₂. Finally, although not illustrated in the figure, dicing is performed on the bar-shaped wafer 100 on the broken line Ly. In other words, the wafer 100 is divided into chips so as to avoid each groove 10A. In this manner, the laser diode 1 of this embodiment is manufactured.

(Actions and Effects of Laser Diode 1)

Next, actions and effects of the laser diode 1 of this embodiment will be described.

In the laser diode 1 of this embodiment, when a predetermined current is supplied to the upper electrode and the lower electrode, the current constricted by the ridge 27 is injected into the current injection region (light emitting region 23A) of the active layer 23, and therefore light emission is generated by recombination of an electron and a hole. This light is reflected by the multilayer reflecting films formed on the front end face S₁ and the rear end face S₂, laser oscillation is generated at a predetermined wavelength, and the light is emitted outside as a beam from the front end face S₁ side.

In Japanese Unexamined Patent Publication No. 2005-236109, it is described to form the stripe grooves and the stripe hills on the top face of the nitride semiconductor substrate (wafer), and form the nitride semiconductor layer on the bottom faces of the grooves and the top faces of the hills. However, in this method, since the grooves extend from end to end of the wafer, although it may be possible to relax the strain in the nitride semiconductor layer in the extending direction of the grooves, it is difficult to relax the strain in the direction intersecting the extending direction of the grooves. Thus, it is difficult to sufficiently relax the strain in the nitride semiconductor layer, and this causes deterioration of device characteristics and reliability in the laser diode.

Meanwhile, in this embodiment, the plurality of strip-shaped grooves 10A satisfying the above-described relational formula are formed on the both sides of the portion (strip-shaped region 27A) facing the ridge 27 in the substrate 10, along the strip-shaped region 27A. Therefore, when the semiconductor layer 20 is formed on the substrate 10 in the manufacturing process, the strain in the semiconductor layer 20 may be relaxed not only in the extending direction of the ridge 27, but also in the direction intersecting the ridge 27. As a result, when the ridge 27 is formed on the substrate 10 in the manufacturing process, it may be possible to reduce the unevenness in the ridge 27. In other words, in this embodiment, it may be possible to realize the laser diode 1 in which the strain is sufficiently relaxed. Therefore, it may be possible to suppress deterioration of the device characteristics and the reliability in the laser diode 1.

### 2. Second Embodiment

(Structure of Laser Diode 2)

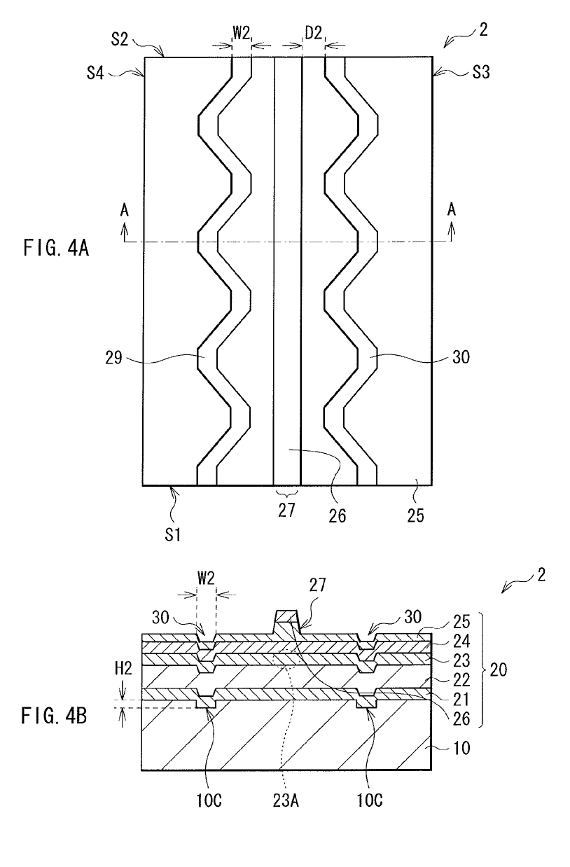

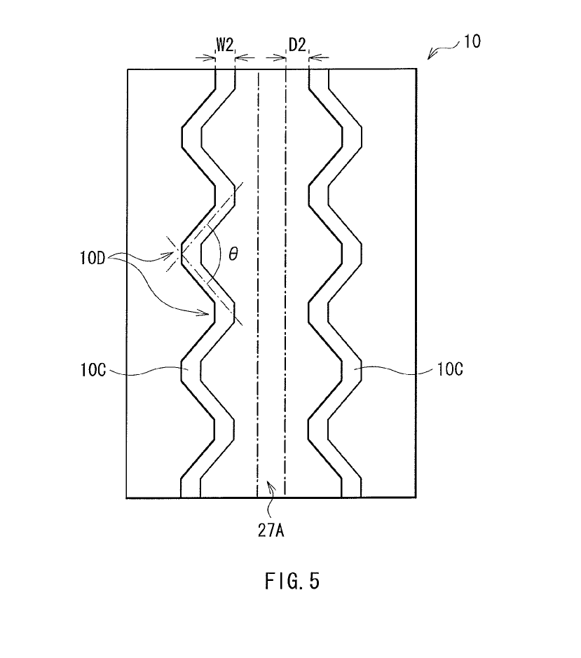

FIG. 4A illustrates an example of the top face structure of a laser diode 2 according to a second embodiment of the present invention. FIG. 4B illustrates an example of the cross-sectional structure as viewed from the direction of arrow A-A of the laser diode 2 of FIG. 4A. FIG. 5 illustrates an example of the top face structure of the substrate 10 in the laser diode 2 of FIGS. 4A and 4B. In addition, FIGS. 4A, 4B, and 5 are schematic illustrations, and are different from actual dimensions and actual shapes.

The structure of the laser diode 2 in this embodiment differs from the structure of the laser diode 1 in the foregoing embodiment in that the laser diode 2 includes strip-shaped grooves 10C in substitution for the grooves 10A, and a strip-shaped recess immediately above each groove 10C in each layer in the semiconductor layer 20. Thus, points different from those of the foregoing embodiment will be mainly described below, and the description of the points common to the foregoing embodiment will be appropriately omitted.

For example, as illustrated in FIG. 5, in this embodiment, the plurality of strip-shaped grooves 10C are provided on the top face (face in contact with the semiconductor layer 20) of the substrate 10. The plurality of grooves 10C are provided on the both sides of the portion (strip-shaped region 27A) facing the ridge 27, along the strip-shaped region 27A. Each groove 10C meanders. Here, for example, as illustrated in FIG. 5, the expression “meander” denotes a concept that a plurality of curve points 10D are intentionally provided on a line, and an example where the plurality of curve points 10D are unintentionally swelled due to manufacture error or the like is excluded. In addition, a curve angle θ in the curve point 10D is not specifically limited, but is set to be, for example, 45°.

Each groove 10C extends in the direction different from the direction orthogonal to the extending direction of the ridge 27, and, for example, extends from the front end face S₁ to the rear end face S₂. Although not illustrated in the figure, each groove 10C may extend from the position slightly away from the front end face S₁ to the position slightly away from the rear end face S₂. In other words, each groove 10C may reach the front end face S₁ and the rear end face S₂, and may not reach the front end face S₁ and the rear end face S₂. Although not illustrated in the figure, each groove 10C may satisfy the following relational formula.

L₄<L₃/2

L₅L₃/3

In the following relational formula, L₄ is a length of each groove 10C, and L₅ is a length of the groove non-form rectangular region in the extending direction of the ridge 27, the groove non-form rectangular region being sandwiched by the grooves 10C from the extending direction of the ridge 27.

Each grove 10C may, for example, extend in the direction intersecting the extending direction of the ridge 27 at the angle other than 90°. Although all the grooves 10C preferably extend in the same direction, some grooves 10C may extend in the direction different from the direction of the other grooves 10C. Although each of the grooves 10C is preferably arranged to be bilaterally symmetric while the ridge 27 is positioned as the center line, each of the grooves 10C may be arranged to be bilaterally asymmetric.

Although a width W₂ of each groove 10C is not specifically limited, for example, the width W₂ is preferably set to be approximately 10 μm or less. Although a depth H₂ (FIG. 4B) of each groove 10C is not specifically limited, for example, the depth H₂ is preferably set to be approximately 10 μm or less. A distance D₂ between each groove 10C and the side face of the ridge 27 is preferably set to be 20 μm or more, and more preferably set to be 50 μm or more. This is because, in the case where the groove 10C is arranged too close to the ridge 27, when the ridge 27 is formed on the substrate 10 in the manufacturing process, there is a possibility that the composition of the ridge 27 is modulated. The distance D₂ is preferably set to be 100 μm or less. This is because, in the case where the groove 10C is arranged too far from the ridge 27, when the ridge 27 is formed on the substrate 10 in the manufacturing process, there is a possibility that large unevenness is generated in the ridge 27.

In this embodiment, in each layer (the buffer layer 21, the lower cladding layer 22, the active layer 23, the electron blocking layer 24, and the upper cladding layer 25) in the semiconductor layer 20, the strip-shaped recess is formed immediately above each groove 10C formed on the substrate 10. In addition, in these recesses, the recess (recess of the upper cladding layer 25) exposed to the top face of the semiconductor layer 20 is described as a recess 30 in FIGS. 4A and 4B. The shape (shape as viewed from the stacking direction) of each recess in the semiconductor layer 20 is the same as the shape of each groove 10C (FIGS. 4A, and 5).

(Method of Manufacturing Laser Diode 2)

The laser diode 2 having such a structure may be manufactured, for example, as will be described next.

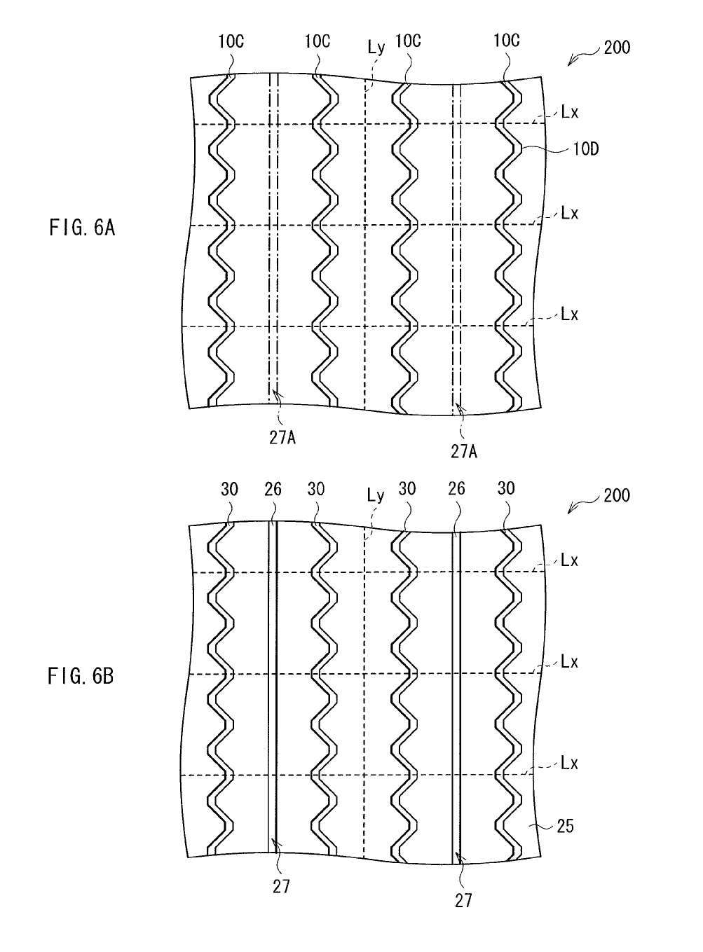

FIGS. 6A and 6B illustrate an example of the top face structure of a wafer 200 in the manufacturing process. In addition, the broken lines Lx and Ly indicated in FIGS. 6A and 6B correspond to the positions where the wafer 200 will be cut later.

First, as the wafer to form the laser diode 2, the wafer 200 including the plurality of strip-shaped grooves 10C on the surface of the substrate 10 is prepared (FIG. 6A). The plurality of grooves 10C on the surface of the wafer 200 are formed on the both sides of each strip-shaped region 27A where the plurality of strip-shaped ridges 27 will be formed later, along the strip-shaped region 27A, and the plurality of grooves 10C meander.

Next, on the wafer 200, for example, the semiconductor layer 20 including the buffer layer 21, the lower cladding layer 22, the active layer 23, the electron blocking layer 24, the upper cladding layer 25, and the contact layer 26 in this order from the substrate 10 side is formed, and the plurality of ridges 27 are formed in the predetermined positions in the semiconductor layer 20 on the upper cladding layer 25 side (FIG. 6B). At this time, the recess 30 is formed immediately above each groove 10C in the surface of the semiconductor layer 20.

Next, although not illustrated in the figure, the upper electrode is formed on the top face of the ridge 27. Further, although not illustrated in the figure, the thickness of the substrate 10 is appropriately adjusted by lapping or the like, if necessary, and then the lower electrode is formed on the rear face of the substrate 10. Next, although not illustrated in the figure, the substrate 10 is cleaved on the broken line Lx, and the wafer 200 is in the bar shape. Therefore, one of the cleavage faces becomes the front end face S₁, and the other of the cleavage faces becomes the rear end face S₂. Thereafter, although not illustrated in the figure, the multilayer reflecting films are formed on the front end face S₁ and the rear end face S₂. Finally, although not illustrated in the figure, dicing is performed on the bar-shaped wafer 200 on the broken line Ly. In this manner, the laser diode 2 of this embodiment is manufactured.

(Actions and Effects of Laser Diode 2)

Next, actions and effects of the laser diode 2 of this embodiment will be described.

In the laser diode 2 of this embodiment, when the predetermined current is supplied to the upper electrode and the lower electrode, the current constricted by the ridge 27 is injected into the current injection region (light emitting region 23A) of the active layer 23, and therefore light emission is generated by recombination of the electron and the hole. This light is reflected by the multilayer reflecting films formed on the front end face S₁ and the rear end face S₂, laser oscillation is generated at the predetermined wavelength, and the light is emitted outside as the beam from the front end face S₁ side.

In this embodiment, the plurality of strip-shaped meandering grooves 10C are formed on the both sides of the portion (strip-shaped region 27A) facing the ridge 27 in the substrate 10, along the strip-shaped region 27A. Therefore, when the semiconductor layer 20 is formed on the substrate 10 in the manufacturing process, the strain in the semiconductor layer 20 may be relaxed not only in the extending direction of the ridge 27, but also in the direction intersecting the ridge 27. As a result, when the ridge 27 is formed on the substrate 10 in the manufacturing process, it may be possible to reduce the unevenness in the ridge 27. In other words, in this embodiment, it may be possible to realize the laser diode 2 in which the strain is sufficiently relaxed. Therefore, it may be possible to suppress deterioration of the device characteristics and the reliability in the laser diode 2.

### 3. Third Embodiment

(Structure of Laser Diode 3)

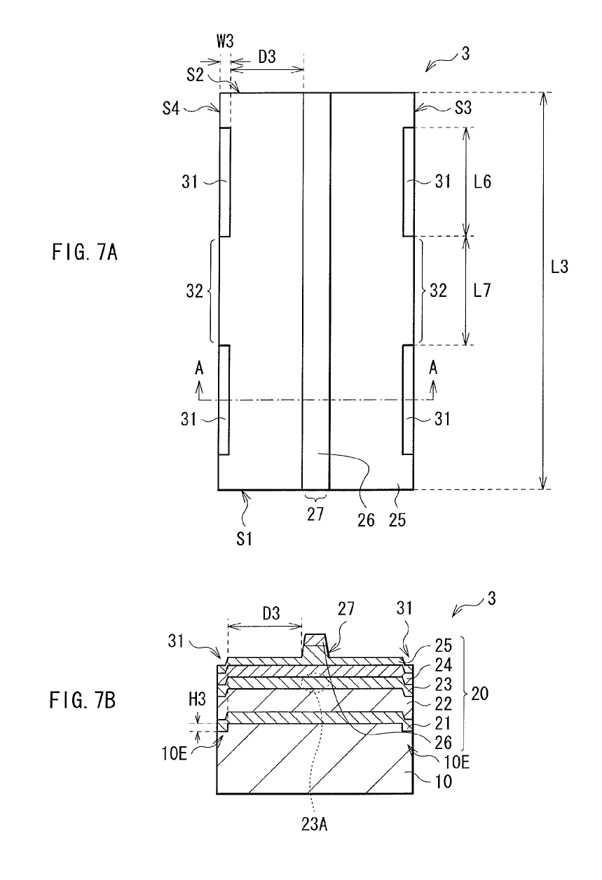

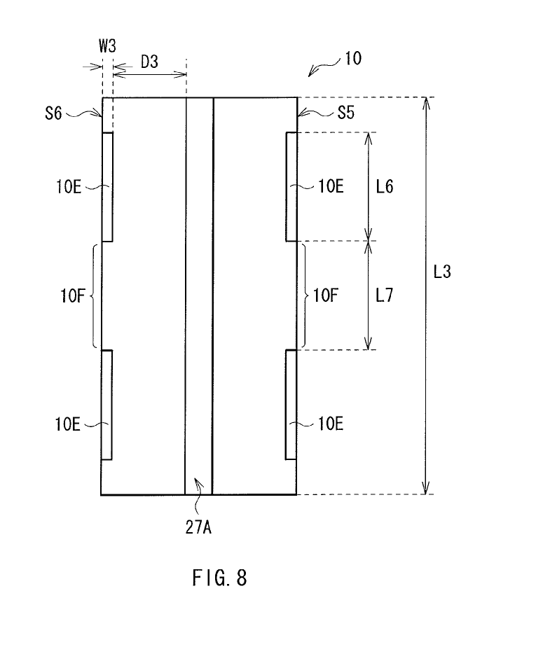

FIG. 7A illustrates an example of the top face structure of a laser diode 3 according to a third embodiment of the present invention. FIG. 7B illustrates an example of the cross-sectional structure as viewed from the direction of arrow A-A of the laser diode 3 of FIG. 7A. FIG. 8 illustrates an example of the top face structure of the substrate 10 in the laser diode 3 of FIGS. 7A and 7B. In addition, FIGS. 7A, 7B, and 8 are schematic illustrations, and are different from actual dimensions and actual shapes.

The structure of the laser diode 3 in this embodiment differs from the structure of the laser diodes 1 and 2 in the foregoing embodiments in that the laser diode 3 includes strip-shaped notches 10E in substitution for the grooves 10A, and the strip-shaped recess immediately above each notch 10E in each layer of the semiconductor layer 20. Thus, points different from those of the foregoing embodiments will be mainly described below, and the description of the points common to the foregoing embodiments will be appropriately omitted.

For example, as illustrated in FIG. 8, in this embodiment, the plurality of strip-shaped notches 10E are provided on the top face (face in contact with the semiconductor layer 20) of the substrate 10, and on side faces S₅ and S₆ of the substrate 10. Each notch 10E extends in the direction different from the direction orthogonal to the extending direction of the ridge 27, and, for example, extends in the extending direction of the ridge 27.

Although a width W₃ of each notch 10E is not specifically limited, for example, the width W₃ is preferably set to be approximately 5 μm or less. Although a depth H₃ (FIG. 7B) of each notch 10E is not specifically limited, for example, the depth H₃ is preferably set to be approximately 10 μm or less. A distance D₃ between each notch 10E and the side face of the ridge 27 is preferably set to be 20 μm or more, and more preferably set to be 50 μm or more. This is because, in the case where the notch 10E (groove 10G which will be described later) is arranged too close to the ridge 27, when the ridge 27 is formed on the substrate 10 in the manufacturing process, there is a possibility that the composition of the ridge 27 is modulated. The distance D₃ is preferably set to be 100 μm or less. This is because, in the case where the notch 10E (groove 10G which will be described later) is arranged too far from the ridge 27, when the ridge 27 is formed on the substrate 10 in the manufacturing process, there is a possibility that the large unevenness is generated in the ridge 27.

A length L₆ of each notch 10E in the resonator direction is, for example, preferably set to be shorter than L₃/2, where L₃ is a resonator length. This indicates that at least one notch non-form rectangular region 10F which will be described later exists on each of the both sides of the strip-shaped region 27A in the top face of the substrate 10. The plurality of notches 10E are arranged side by side in the extending direction of the ridge 27.

For example, as illustrated in FIG. 8, on the top face of the substrate 10, a region (notch non-form rectangular region 10F) sandwiched by the notches 10E from the extending direction of the ridge 27 exists. At least one notch non-form rectangular region 10F exists on each of the both sides of the ridge 27, and a length L₇ of each notch non-form rectangular region 10F in the resonator direction is, for example, preferably set to be L₃/3 or less.

In this embodiment, in each layer (the buffer layer 21, the lower cladding layer 22, the active layer 23, the electron blocking layer 24, and the upper cladding layer 25) in the semiconductor layer 20, the strip-shaped recess is formed immediately above each notch 10E formed on the substrate 10. In addition, in these recesses, the recess (recess of the upper cladding layer 25) exposed to the top face of the semiconductor layer 20 is described as a recess 31 in FIGS. 7A and 7B. The shape (shape as viewed from the stacking direction) of each recess in the semiconductor layer 20 is the same as the shape of each notch 10E (FIGS. 7A and 8). For example, as illustrated in FIG. 7A, on the top face of the semiconductor layer 20, a region (notch non-form rectangular region 32) sandwiched by the recesses 31 from the extending direction of the ridge 27 exists. The length of each notch non-form rectangular region 32 in the resonator direction is set to be equal to the length L₇ of each notch non-form rectangular region 10F in the resonator direction (FIG. 7A).

(Method of Manufacturing Laser Diode 3)

The laser diode 3 having such a structure may be manufactured, for example, as will be described next.

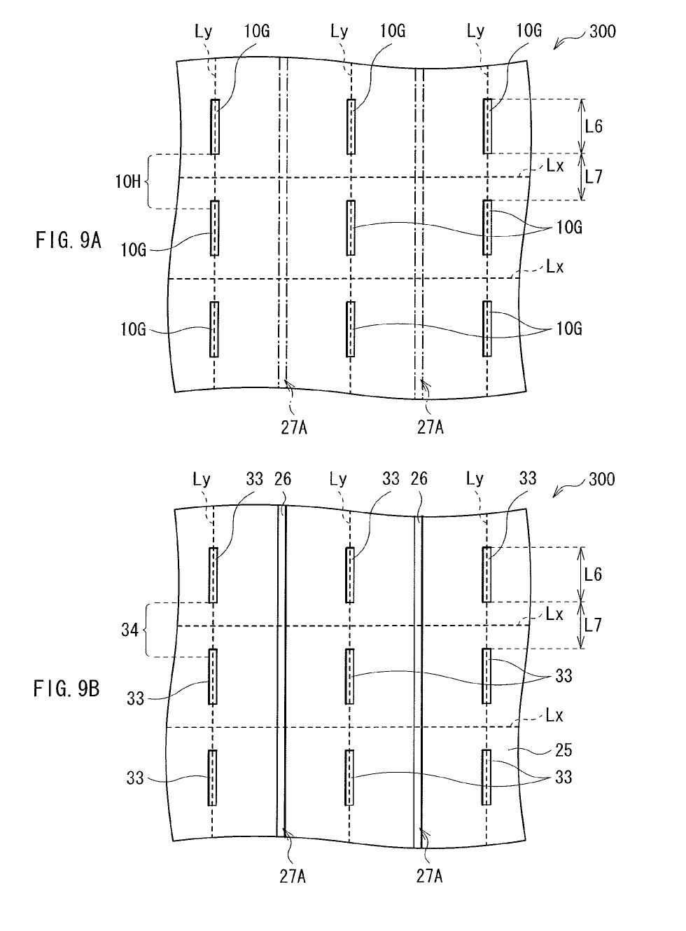

FIGS. 9A and 9B illustrate an example of the top face structure of a wafer 300 in the manufacturing process. In addition, the broken lines Lx and Ly indicated in FIGS. 9A and 9B correspond to the positions where the wafer 300 will be cut later. Here, the broken line Lx is arranged so as to avoid each groove 10G, while the broken line Ly is arranged so as to extend longitudinally across each groove 10G.

First, as the wafer to form the laser diode 3, the wafer 300 including the plurality of strip-shaped grooves 10G on the surface of the substrate 10 is prepared (FIG. 9A). The plurality of grooves 10G on the surface of the wafer 300 are formed on the both sides of each strip-shaped region 27A where the plurality of strip-shaped ridges 27 will be formed later, along the strip-shaped region 27A, and satisfy the following relational formula.

L₆<L₃/2

L₇≦L₃/3

Next, on the wafer 300, for example, the semiconductor layer 20 including the buffer layer 21, the lower cladding layer 22, the active layer 23, the electron blocking layer 24, the upper cladding layer 25, and the contact layer 26 in this order from the substrate 10 side is formed, and the plurality of ridges 27 are formed in the predetermined positions in the semiconductor layer 20 on the upper cladding layer 25 side (FIG. 9B). At this time, a recess 33 is formed immediately above each groove 10G in the surface of the semiconductor layer 20.

Next, although not illustrated in the figure, the upper electrode is formed on the top face of the ridge 27. Further, although not illustrated in the figure, the thickness of the substrate 10 is appropriately adjusted by lapping or the like, if necessary, and then the lower electrode is formed on the rear face of the substrate 10. Next, although not illustrated in the figure, the substrate 10 is cleaved on the broken line Lx, and the wafer 300 is in the bar shape. Therefore, one of the cleavage faces becomes the front end face S₁, and the other of the cleavage faces becomes the rear end face S₂. Thereafter, although not illustrated in the figure, the multilayer reflecting films are formed on the front end face S₁ and the rear end face S₂. Finally, although not illustrated in the figure, dicing is performed on the bar-shaped wafer 300 on the broken line Ly. In other words, the bar-shaped wafer 300 is divided into the chips while cutting each groove 10G. Therefore, each groove 10G is cut and becomes the notch 10E, and each recess 33 is cut and becomes the recess 31. In this manner, the laser diode 3 of this embodiment is manufactured.

(Actions and Effects of Laser Diode 3)

Next, actions and effects of the laser diode 3 of this embodiment will be described.

In the laser diode 3 of this embodiment, when the predetermined current is supplied to the upper electrode and the lower electrode, the current constricted by the ridge 27 is injected into the current injection region (light emitting region 23A) of the active layer 23, and therefore light emission is generated by recombination of the electron and the hole. This light is reflected by the multilayer reflecting films formed on the front end face S₁ and the rear end face S₂, laser oscillation is generated at the predetermined wavelength, and the light is emitted outside as the beam from the front end face S₁ side.

In this embodiment, the plurality of strip-shaped notches 10E satisfying the above-described relational formula are formed on the side faces S₅ and S₆ of the substrate 10. Here, each notch 10E is, for example, formed by cutting the groove 10G provided on the substrate 10, when the wafer 300 (substrate 10) is cut in the manufacturing process. In this manner, in this embodiment, since the groove 10G corresponding to the above-described relational formula is provided on the substrate 10, when the semiconductor layer 20 is formed on the substrate 10 in the manufacturing process, the strain in the semiconductor layer 20 may be relaxed not only in the extending direction of the ridge 27, but also in the direction intersecting the ridge 27. As a result, when the ridge 27 is formed on the substrate 10 in the manufacturing process, it may be possible to reduce the unevenness in the ridge 27. In other words, in this embodiment, it may be possible to realize the laser diode 3 in which the strain is sufficiently relaxed. Therefore, it may be possible to suppress deterioration of the device characteristics and the reliability in the laser diode 3.

Although the present invention has been described with the plurality of embodiments, the present invention is not limited to the foregoing embodiments, and various modifications may be made.

For example, in the foregoing embodiments, although the case where each of the laser diodes 1 to 3 includes only one ridge 27 has been described, each of the laser diodes 1 to 3 may include the plurality of ridges 27.

The present application contains subject matter related to that disclosed in Japanese Priority Patent Application JP 2009-283447 filed in the Japan Patent Office on Dec. 14, 2009, the entire contents of which is hereby incorporated by reference.

It should be understood by those skilled in the art that various modifications, combinations, sub-combinations and alternations may occur depending on design requirements and other factors insofar as they are within the scope of the appended claims or the equivalents thereof.

What is claimed is:

1. A laser diode comprising:
a substrate;
a semiconductor layer including a lower cladding layer, an active layer, and an upper cladding layer in this order from a substrate side;
a strip-shaped ridge provided on an upper cladding layer side in the semiconductor layer; and
a pair of resonator end faces sandwiching the semiconductor layer and the ridge from an extending direction of the ridge, wherein
the substrate includes a plurality of strip-shaped grooves provided on both sides of a portion facing the ridge along the portion facing the ridge, and extending in a direction different from a direction orthogonal to the extending direction of the ridge, and
L₁, L₂, and L₃ satisfy the following relationship,
L₁<L₃/2
L₂≦L₃/3
where L₁ is a length of each groove, L₂ is a length of a groove non-form rectangular region in the extending direction of the ridge, the groove non-form rectangular region being sandwiched by the grooves from the extending direction of the ridge, and L₃ is a resonator length.

2. The laser diode according to claim 1, wherein the plurality of grooves are arranged side by side in the extending direction of the ridge.

3. A laser diode comprising:
a substrate;
a semiconductor layer including a lower cladding layer, an active layer, and an upper cladding layer in this order from a substrate side;
a strip-shaped ridge provided on an upper cladding layer side in the semiconductor layer; and
a pair of resonator end faces sandwiching the semiconductor layer and the ridge from an extending direction of the ridge, wherein
the substrate includes a plurality of strip-shaped grooves provided on both sides of a portion facing the ridge along the portion facing the ridge, and extending in the extending direction of the ridge, and
the plurality of grooves meander.

4. The laser diode according to claim 3, wherein the grooves extend from one of the resonator end faces to the other of the resonator end faces.

5. A laser diode comprising:
a substrate;
a semiconductor layer including a lower cladding layer, an active layer, and an upper cladding layer in this order from a substrate side;
a strip-shaped ridge provided on an upper cladding layer side in the semiconductor layer; and
a pair of resonator end faces sandwiching the semiconductor layer and the ridge from an extending direction of the ridge, wherein
the substrate includes a pair of side faces facing in a direction orthogonal to the extending direction of the ridge, and includes a plurality of strip-shaped notches on both of the pair of side faces, and
L₁, L₂, and L₃ satisfy the following relationship,
L₁<L₃/2
L₂≦L₃/3
where L₁ is a length of each notch, L₂ is a length of a notch non-form region in the extending direction of the ridge, the notch non-form region being sandwiched by the notches from the extending direction of the ridge, and L₃ is a resonator length.

6. A method of manufacturing a laser diode comprising:
a first step of preparing a substrate including a plurality of strip-shaped grooves provided on both sides of each strip-shaped region where a plurality of strip-shaped ridges will be formed later, along the strip-shaped region, and satisfying the following relational formula,
L₁<L₃/2
L₂≦L₃/3
where L₁ is a length of each groove, L₂ is a length of a groove non-form rectangular region in the extending direction of the ridge, the groove non-form rectangular region being sandwiched by the grooves from the extending direction of the ridge, and L₃ is a resonator length;
a second step of forming a semiconductor layer including a lower cladding layer, an active layer, and an upper cladding layer in this order from the substrate side on a surface of the substrate, and forming the plurality of ridges on the upper cladding layer side in the semiconductor layer; and
a third step of cutting the substrate into chips.

7. The method of manufacturing a laser diode according to claim 6, wherein the substrate is divided into the chips so as to avoid each groove in the third step.

8. The method of manufacturing a laser diode according to claim 6, wherein the substrate is divided into the chips so as to cut each groove in the third step.

9. A method of manufacturing a laser diode comprising:
a first step of preparing a substrate including a plurality of strip-shaped meandering grooves provided on both sides of each strip-shaped region where a plurality of strip-shaped ridges will be formed later, along the strip-shaped region;
a second step of forming a semiconductor layer including a lower cladding layer, an active layer, and an upper cladding layer in this order from a substrate side on a surface of the substrate, and forming the plurality of ridges on an upper cladding layer side in the semiconductor layer; and
a third step of cutting the substrate into chips.
